(19) United States
(12) Patent Application Publication
(10) Pub. No.: US 2024/0077557 A1
(43) Pub. Date: Mar. 7, 2024

(54) SUPERCONDUCTING MAGNET AND MRI APPARATUS

(71) Applicant: CANON MEDICAL SYSTEMS CORPORATION, Otawara-shi (JP)

(72) Inventors: Takehiro SHIBUYA, Nasushiobara (JP); Hiromi KAWAMOTO, Yaita (JP)

(73) Assignee: CANON MEDICAL SYSTEMS CORPORATION, Otawara-shi (JP)

(21) Appl. No.: 18/455,752

(22) Filed: Aug. 25, 2023

(30) Foreign Application Priority Data
Sep. 1, 2022 (JP) 2022-139213

(51) Int. Cl. G01R 33/3815; H01F 6/06

(52) U.S. Cl. CPC G01R 33/3815; H01F 6/06

(57) ABSTRACT

In one embodiment, a superconducting magnet includes: at least one set of coil segment including a first coil segment formed of a superconducting wire through which an electric current flows in a forward direction, and a second coil segment formed of the superconducting wire through which an electric current flows in a direction opposite to the forward direction; and at least one intermediate wiring provided between the first coil segment and the second coil segment and configured to connect the first coil segment and the second coil segment without disconnection and change directions of electric currents such that that the electric current flows through the first coil segment in the forward direction and the electric current flows through the second coil segment in a direction opposite to the forward direction.

### CROSS-REFERENCE TO RELATED APPLICATION

This application is based upon and claims the benefit of priority from Japanese Patent Application No. 2022-139213, filed on Sep. 1, 2022, the entire contents of which are incorporated herein by reference.

### TECHNICAL FIELD

Disclosed embodiments relate to a superconducting magnet and a magnetic resonance imaging (MRI) apparatus.

### BACKGROUND

An MRI apparatus is an imaging apparatus that magnetically excites nuclear spin of an object placed in a static magnetic field by applying a radio frequency (RF) signal having the Larmor frequency and reconstructs an image on the basis of magnetic resonance (MR) signals emitted from the object due to the excitation.

An MRI apparatus includes a static magnetic field magnet for generating a static magnetic field. In particular, in an MRI apparatus installed in a medical institution such as a hospital for examination and diagnosis, a considerably strong static magnetic field is required, and thus a superconducting magnet is used.

In a static magnetic field magnet using a superconducting magnet, a superconducting coil is cooled down to an extremely low temperature by, for example, liquid helium. In a conventional static magnetic field magnet, desired static magnetic field distribution is obtained by arranging a plurality of superconducting coils with different diameters and/or different number of turns at different positions.

In the conventional static magnetic field magnet, the respective superconducting coils are connected by using various joint means such as soldering joint or press joint. In the following, the joint means between superconducting coils is collectively referred to as “superconducting joint”.

Although the superconducting joint is exposed to the same cryogenic environment similarly to the superconducting coil, the superconducting joint has a minute but finite resistance value due to resistance of the solder layer interposed between the superconducting filaments at the joint point, and/or resistance of the oxide layer of the superconducting filament, for example.

In general, a time constant τ of magnetic field attenuation after shifting to a persistent current mode is defined by τ=L/R, wherein “L” is the inductance of the superconducting coil and “R” is the resistance value of the entire superconducting coil. In the persistent current mode, the resistance value of each superconducting coil becomes substantially zero, and thus, the resistance value R of the entire superconducting coil is dominated by the resistance value of the above-described superconducting joint.

Hence, in order to lengthen a duration time of the persistent current mode (i.e., increase the time constant τ of magnetic field attenuation), the resistance value of the superconducting joint is preferably to be reduced as much as possible.

In particular, in a superconducting magnet with relatively small static magnetic field strength, the inductance L of the superconducting coil is also small, and thus, the duration time of the persistent current mode can be lengthened by correspondingly reducing the resistance value of the superconducting joint as much as possible.

### BRIEF DESCRIPTION OF THE DRAWINGS

In the accompanying drawings:

FIG. 1 is a block diagram illustrating an overall configuration of an MRI apparatus according to one embodiment;

FIG. 2 is a schematic diagram illustrating a first aspect of a flat-plate superconducting magnet;

FIG. 3 is a schematic diagram illustrating a second aspect of the flat-plate superconducting magnet;

FIG. 4A is a perspective view schematically illustrating a configuration of a cylindrical superconducting magnet;

FIG. 4B is a cross-sectional view schematically illustrating an internal structure of the cylindrical superconducting magnet;

FIG. 5A is a perspective view schematically illustrating a configuration of flat-plate superconducting magnets;

FIG. 5B is a cross-sectional view schematically illustrating an internal structure of the flat-plate superconducting magnets;

FIG. 6A is a cross-sectional view of the superconducting magnets;

FIG. 6B is an enlarged cross-sectional view of one of the two superconducting magnets;

FIG. 7 is a schematic diagram illustrating details of a winding frame and a superconducting coil;

FIG. 8A is a schematic diagram illustrating the superconducting joint used in a conventional superconducting magnet;

FIG. 8B is a schematic diagram illustrating an aspect in which the number of the superconducting joint is reduced in the superconducting magnet of the embodiment;

FIG. 9A is a schematic diagram illustrating a configuration of the superconducting magnet according to a first modification of the embodiment;

FIG. 9B is a schematic diagram illustrating a configuration of the superconducting magnet according to a second modification of the embodiment;

FIG. 10A is the same diagram as FIG. 9A;

FIG. 10B is a schematic diagram illustrating a configuration of the superconducting magnet according to a third modification of the embodiment;

FIG. 11A is a schematic diagram illustrating a configuration of the superconducting magnet according to a fourth modification of the embodiment; and

FIG. 11B is an equivalent circuit diagram of the superconducting magnet of the fourth modification.

### DETAILED DESCRIPTION

Hereinbelow, embodiments of the present invention will be described by referring to the accompanying drawings.

In one embodiment, a superconducting magnet includes: at least one set of coil segment including a first coil segment formed of a superconducting wire through which an electric current flows in a forward direction, and a second coil segment formed of the superconducting wire through which an electric current flows in a direction opposite to the forward direction; and at least one intermediate wiring provided between the first coil segment and the second coil segment and configured to connect the first coil segment and the second coil segment without disconnection and change directions of electric currents such that that the electric current flows through the first coil segment in the forward direction and the electric current flows through the second coil segment in a direction opposite to the forward direction.

(MRI Apparatus)

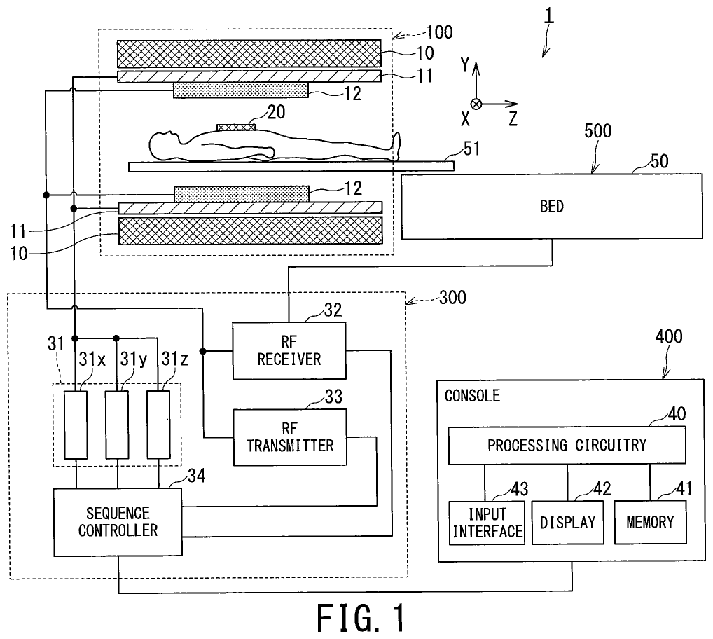

FIG. 1 is a block diagram illustrating an overall configuration of an MRI apparatus 1 provided with a superconducting magnet 10 according to the first embodiment. The MRI apparatus 1 includes: a gantry 100; a bed 500; a control cabinet 300; and a console 400, for example.

The gantry 100 includes a superconducting magnet 10, a gradient coil 11, and a WB (Whole Body) coil 12, and these components are housed in a cylindrical housing. The bed 500 includes a bed body 50 and a table 51. The MRI apparatus 1 also includes at least one local coil 20 disposed close to an object.

The control cabinet 300 includes three gradient coil power supplies 31 (31x for an X-axis, 31y for a Y-axis, and 31z for a Z-axis), an RF receiver 32, an RF transmitter 33, and a sequence controller 34.

The superconducting magnet 10 of the gantry 100 is substantially in the form of a cylinder and generates a static magnetic field inside a bore, which is a space inside the cylindrical structure of the superconducting magnet 10 and serves as an imaging region of an object such as a patient. The superconducting magnet 10 includes at least one superconducting coil inside, and the superconducting coil is cooled down to an extremely low temperature by a coolant such as liquid helium or by a conduction cooling method, for example. The superconducting magnet 10 generates a static magnetic field by applying an electric current supplied from a static-magnetic-field power supply (not shown) to the superconducting coil in an excitation mode. Afterward, the superconducting magnet 10 shifts to a persistent current mode, and the static-magnetic-field power supply is disconnected. Once it shifts to the persistent current mode, the superconducting magnet 10 continues to generate a strong static magnetic field for a long time, for example, over one year. The configuration and function of the superconducting magnet 10 according to the embodiment will be described below in detail.

The gradient coil 11 is also substantially in the form of a cylinder and is fixed to the inside of the superconducting magnet 10. This gradient coil 11 applies gradient magnetic fields to the object in the respective directions of the X-axis, the Y-axis, and the Z-axis by using electric currents supplied from the respective gradient coil power supplies 31x, 31y, and 31z.

The bed body 50 of the bed 500 is configured to move the table 51 in the vertical direction, and moves the table 51 with the object placed thereon to a predetermined height before imaging. Afterward, during time of imaging, the bed body 50 moves the table 51 in the horizontal direction so as to move the object to the inside of the bore.

The WB coil 12 is substantially formed into a cylindrical shape and fixed to the inside of the gradient coil 11 so as to surround the object. The WB coil 12 applies RF pulses transmitted from the RF transmitter 33 to the object, and receives MR signals emitted from the object due to excitation of hydrogen nuclei.

The local coil 20 is also called a surface coil or an RF coil, and receives MR signals emitted from the object at a position close to the body surface of the object. The local coil 20 includes a plurality of coil elements, for example. There are various local coils 20 adaptable to the anatomical imaging part of the object, such as the head, the chest, the spine, the lower limbs, for the whole body. FIG. 1 illustrates the local coil 20 for imaging the chest.

The RF transmitter 33 transmits RF pulses to the WB coil 12 based on an instruction from the sequence controller 34. The RF receiver 32 receives MR signals detected by the WB coil 12 and/or the local coil 20, and transmits raw data obtained by digitizing the detected MR signals to the sequence controller 34.

The sequence controller 34 performs a scan of the object by driving the gradient coil power supplies 31, the RF transmitter 33, and the RF receiver 32 under the control of the console 400. The sequence controller 34 receives the raw data acquired by the scan from the RF receiver 32 and then transmits the raw data to the console 400.

The sequence controller 34 includes processing circuitry (not shown). This processing circuitry is configured as hardware such as a processor for executing predetermined programs, a field programmable gate array (FPGA), and an application specific integrated circuit (ASIC), for example.

The console 400 is configured as a computer that includes processing circuitry 40, a memory 41, an input interface 43, and a display 42.

The memory 41 is a recording medium including a read-only memory (ROM) and a random access memory (RAM) in addition to an external memory device such as a hard disk drive (HDD) and an optical disc device. The memory 41 stores various programs to be executed by a processor of the processing circuitry 40 in addition to various data and information.

The input interface 43 includes various devices for a user to input various data and information, and is configured as, for example, a mouse, a keyboard, a trackball, and/or a touch panel.

The display 42 is a display device such as a liquid crystal display panel, a plasma display panel, and an organic EL panel.

The processing circuitry 40 is, for example, a circuit provided with a CPU and/or a special-purpose or general-purpose processor. The processor implements various functions by executing programs stored in the memory 41. The processing circuitry 40 may be configured with hardware such as an FPGA and an ASIC. The processing circuitry 40 can implement various functions by combining hardware processing and software processing based on its processor and programs.

The console 400 controls the entirety of the MRI apparatus 1. Specifically, the console 400 receives various instructions and information such as imaging conditions that are inputted by a user such as a medical imaging technologist through the mouse and/or the keyboard of the input interface 43. The processing circuitry 40 causes the sequence controller 34 to perform a scan on the basis of the inputted imaging conditions, and reconstructs images on the basis of the raw data transmitted from the sequence controller 34. The reconstructed images are displayed on the display 42 and stored in the memory 41.

Since the superconducting magnet 10, the gradient coil 11, and the WB coil 12 are cylindrical in the MRI apparatus 1 shown in FIG. 1, this type of MRI apparatus 1 is hereinafter referred to as a cylindrical MRI apparatus, and this type of superconducting magnet 10 is hereinafter referred to as a cylindrical superconducting magnet 10.

In a cylindrical MRI apparatus, imagining is performed in a cylindrical closed space, which may be difficult for a patient with claustrophobia, for example.

Another type of a MRI apparatus that has been proposed and developed includes two flat-plate superconducting magnets and flat-plate gradient coils 11, and is configured to image the object such as a patient in an open space sandwiched between the two flat-plate superconducting magnets 10, for example. This type of MRI apparatus is hereinafter referred to as a planar open type MRI apparatus or an open MRI apparatus. Since the open MRI apparatus performs imaging in an open space, a patient with claustrophobia can be imaged. Hereinafter, a superconducting magnet 10 of this shape is referred to as a flat-plate superconducting magnet 10.

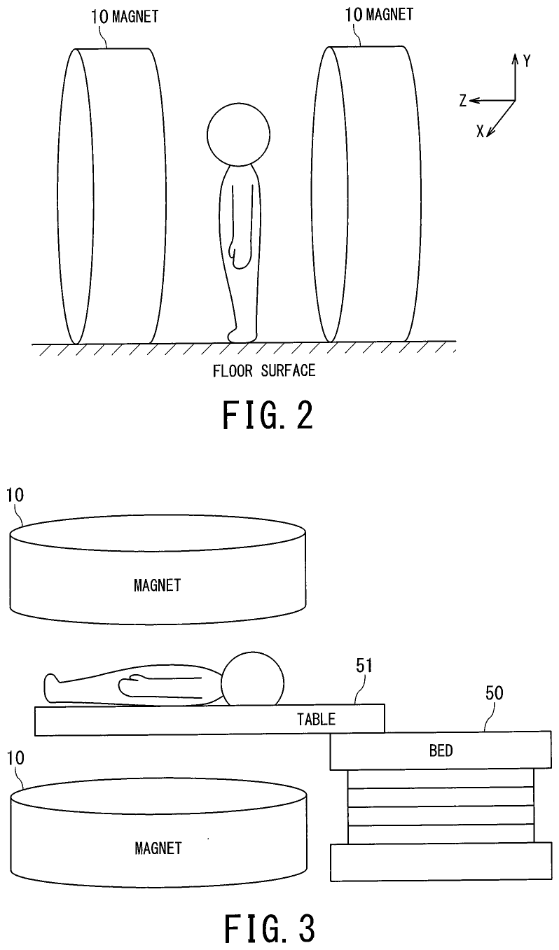

FIG. 2 is a schematic diagram illustrating a first aspect of flat-plate superconducting magnets 10. The first aspect is, for example, two flat-plate superconducting magnets suitable for imaging an object in a standing position. In the first aspect, the two flat-plate superconducting magnets are arranged such that their cylindrical axes (i.e., Z-axis direction in FIG. 2) are coaxial and horizontal, and an upright object is positioned and imaged in the imaging space sandwiched between the two flat-plate superconducting magnets 10.

FIG. 3 is a schematic diagram illustrating a second aspect of the flat-plate superconducting magnets 10. In addition to the flat-plate superconducting magnets 10, the bed body 50 and the table 51 are also illustrated in FIG. 3. The second aspect is, for example, flat-plate superconducting magnets 10 suitable for imaging an object lying on the table 51. In the second aspect, the two flat-plate superconducting magnets 10 are arranged such that their cylindrical axes are coaxial and vertical, and the object lying on the table 51 is positioned and imaged in the imaging space sandwiched between the two flat-plate superconducting magnets 10.

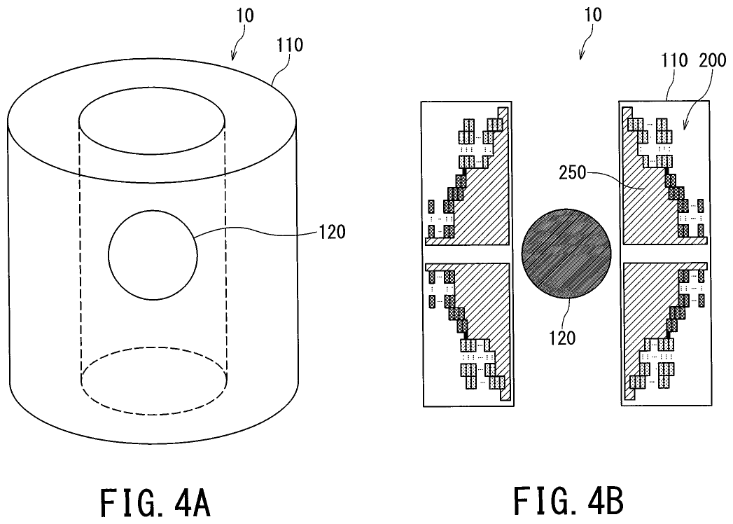

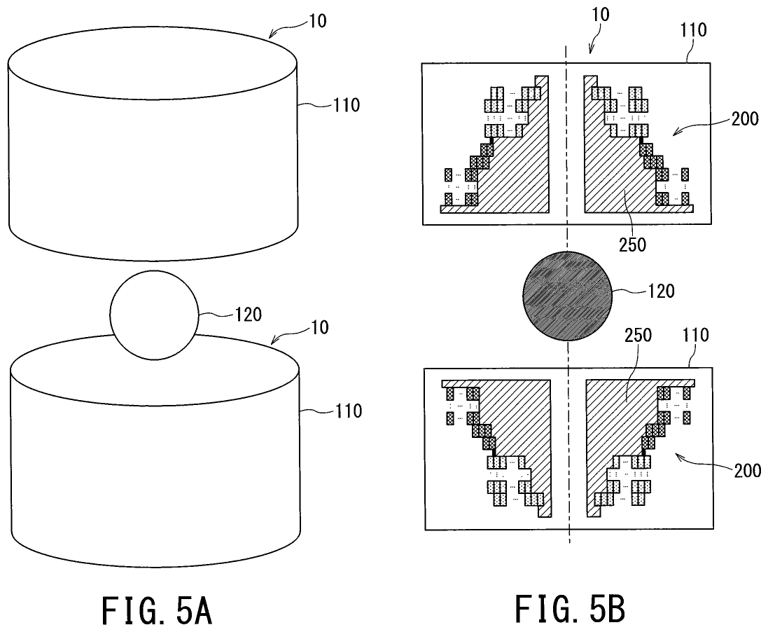

FIG. 4A is a perspective view schematically illustrating a configuration of the cylindrical superconducting magnet 10. FIG. 4B is a cross-sectional view schematically illustrating an internal structure of the cylindrical superconducting magnet 10. In FIG. 4A and FIG. 4B, the cylindrical axis is intentionally illustrated as a vertical axis for comparison with the flat-plate superconducting magnet 10 (FIG. 5A and FIG. 5B) described below.

As shown in FIG. 4A and FIG. 4B, the cylindrical superconducting magnet 10 has a cylindrical vacuum vessel 110, and an imaging space 120 is formed in the cylindrical hollow region.

As shown in FIG. 4B, inside the vacuum vessel 110, a superconducting coil 200 and a winding frame 250 that winds around the superconducting coil 200 are arranged.

FIG. 5A is a perspective view schematically illustrating a configuration of the flat-plate superconducting magnets 10, and FIG. 5B is a cross-sectional view schematically illustrating an internal structure of the flat-plate superconducting magnets 10.

FIG. 5A and FIG. 5B show the configuration of two flat-plate superconducting magnets 10 arranged on the respective upper and lower sides. Each flat-plate superconducting magnet has a cylindrical vacuum vessel 110 that has flat surfaces on its top and bottom, and an imaging space 120 is formed in an open space region sandwiched between the two flat-plate superconducting magnets 10 in the vertical direction.

As shown in FIG. 5B, inside each vacuum vessel 110, the superconducting coil 200 and the winding frame 250 that winds around the superconducting coil 200 are arranged. Both flat-plate superconducting magnets 10 have substantially the same configuration and structure. As is clear from FIG. 5B, one flat-plate superconducting magnets 10 is disposed upside down with respect to the other one. Details of the configuration and structure of each superconducting coil 200 and each winding frame 250 will be described below.

Although the configuration, structure, and/or characteristics of one flat-plate superconducting magnets 10 will be described below, these descriptions hold true for the other flat-plate superconducting magnets 10 and also hold true for the cylindrical superconducting magnet 10 shown in FIG. 4A and FIG. 4B. Thus, hereinafter, both the flat-plate superconducting magnet 10 and the cylindrical superconducting magnet 10 are simply referred to as the superconducting magnet 10.

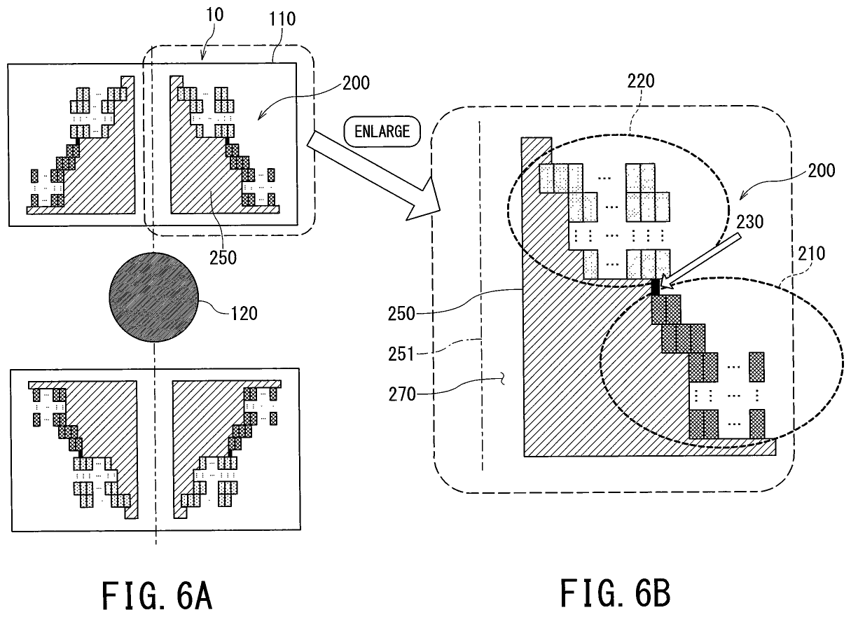

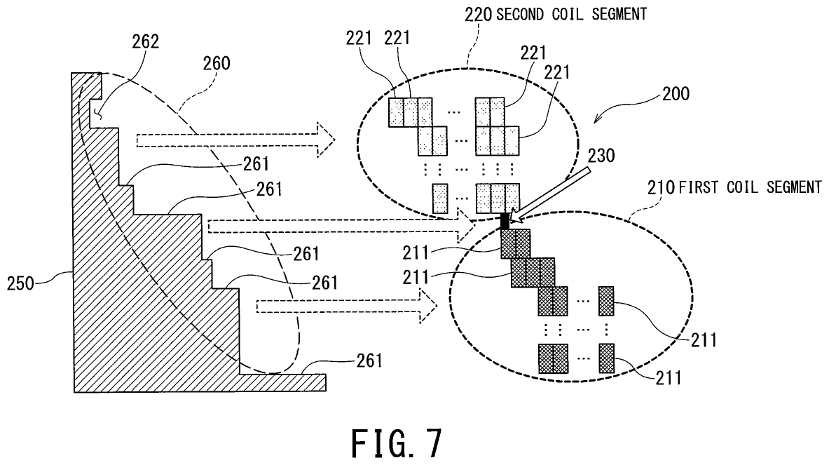

FIG. 6A, FIG. 6B, and FIG. 7 illustrate the configuration of the superconducting magnet 10 according to the embodiment, particularly the configuration and structure of the superconducting coil 200 and the winding frame 250 of the superconducting magnet 10.

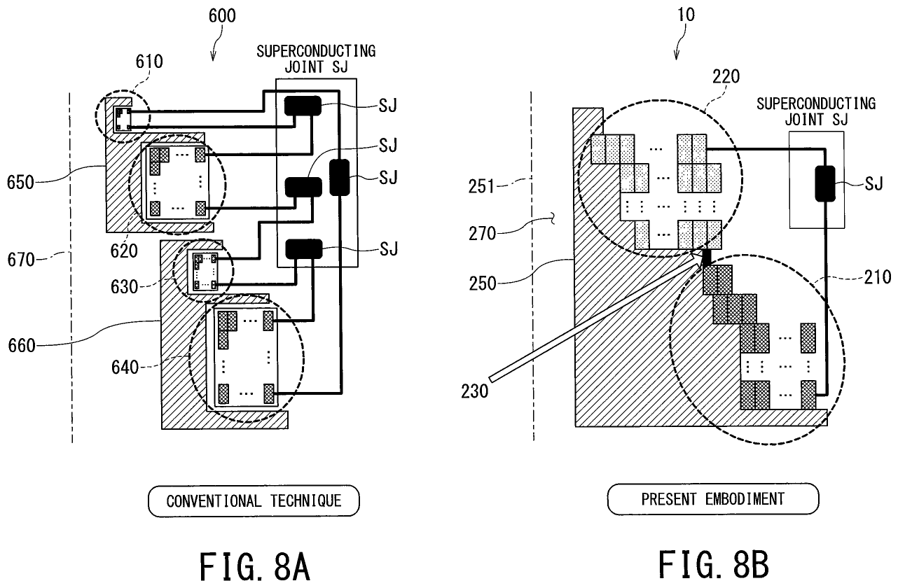

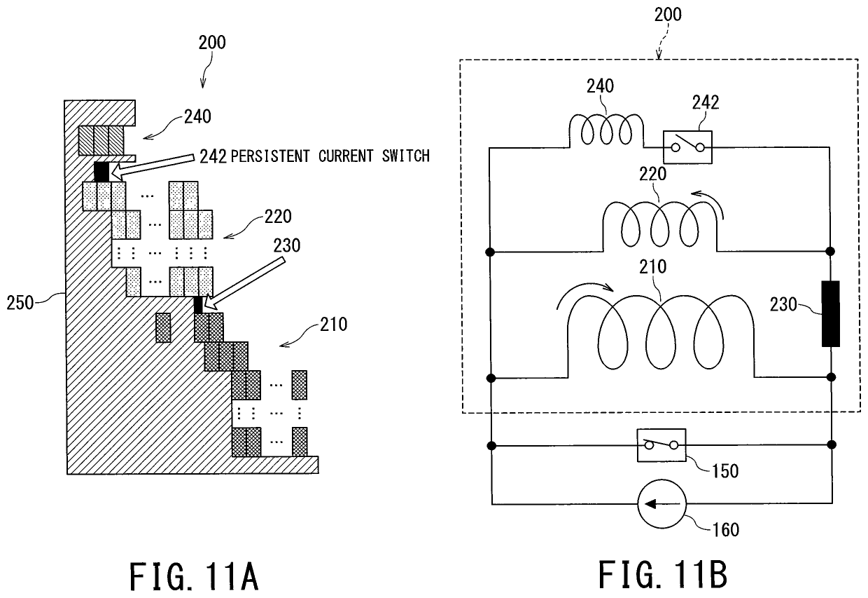

FIG. 6A is a cross-sectional view of the same superconducting magnet 10 as FIG. 5B, and FIG. 6B is an enlarged cross-sectional view of one of the two superconducting magnets 10. As described above, the two superconducting magnets 10 have the same shape and structure, and each superconducting magnet 10 has a shape and structure that are axially symmetrical with respect to the central axis 251 of its cylindrical body. Thus, of the bilaterally symmetrical cross-sectional views of one superconducting magnet 10 (upper superconducting magnet 10), the right cross-sectional view will be used in the following for describing the configuration, structure, and characteristics of the superconducting magnet 10 as shown in FIG. 6B, FIG. 7, FIG. 8A to FIG. 10B, and FIG. 11B.

The superconducting magnet 10 of the embodiment includes at least the superconducting coil 200 and the winding frame 250 that winds around the superconducting coil 200, as shown in FIG. 6B.

The superconducting coil 200 includes a first coil segment 210 through which an electric current flows in the forward direction as a forward current, a second coil segment 220 through which an electric current flows in the direction opposite to the forward direction, and an intermediate wiring 230 that connects the first coil segment 210 and the second coil segment 220 without disconnecting or severing both. Each of the first and second coil segments 210 and 220 and the intermediate wiring 230 is formed by using an ultra-fine multifilamentary wire structure in which a superconducting material such as niobium titanium (Nb—Ti) is made into many thin filaments and embedded in a normal-conduction base material such as copper. Alternatively, each of the first and second coil segments 210 and 220 and the intermediate wiring 230 is formed by using a rare earth-based or bismuth-based high-temperature superconducting wire in a tape shape, for example.

The intermediate wiring 230 is wound in a manner to make the current flowing through the first coil segment 210 and the current flowing through the second coil segment 220 flow in opposite directions. By having the direction of the current flowing in the first coil segment 210 opposite to the direction of the current flowing in the second coil segment 220, the direction of the first magnetic field generated by the first coil segment 210 and the direction of the second magnetic field generated by the second coil segment 220 can be made opposite to each other. By combining such first and second magnetic fields, the distribution shape and the strength of the static magnetic field can be arranged with a higher degree of freedom.

In addition, the intermediate wiring 230 may be a wiring that is non-inductively wound. The non-inductive winding is a winding method by which the magnetic field generated by the intermediate wiring 230 becomes substantially zero. For example, by winding a first wiring in the first direction and a second wiring in the second direction opposite to the first direction with the same wiring length in a superimposed manner in the same position or region, the wiring with non-inductive winding can be provided.

Since the magnetic field generated by the intermediate wiring 230 can be made substantially zero (i.e., infinitely small) by non-inductively winding the intermediate wiring 230 as described above, the static magnetic field distribution formed by the first and second coil segments 210 and 220 is not affected by the intermediate wiring 230.

It should be noted that each of the first and second coil segments 210 and 220 and the intermediate wiring 230 is a superconducting wire, and these (210, 220, 230) are formed of one continuous superconducting wire without using the superconducting joint.

By contrast, as described above, the superconducting joint is a joint means which enables separate superconducting wires to be connected by using soldering joint or press joint, for example.

The winding frame 250 is a frame that winds around the superconducting coil 200 (i.e., the first coil segment 210, the second coil segment 220, and the intermediate wiring 230). In particular, the winding frame 250 of the embodiment is formed in a manner that facilitates positioning of the first and second coil segments 210 and 220 and the intermediate wiring 230.

The winding frame 250 may be formed by processing a single cylindrical member, or by processing a stack of a plurality of cylindrical members, for example. A cylindrical hollow region 270 is formed in the center of the cylindrical member. When the superconducting magnet 10 is formed as a cylindrical superconducting magnet 10, this hollow region 270 serves as the imaging space of the object.

Note that the superconducting coil 200 may be configured to comprise at least one coil segment including a first coil segment formed of a superconducting wire through which an electric current flows in a forward direction, and a second coil segment formed of the superconducting wire through which an electric current flows in a direction opposite to the forward direction; and at least one intermediate wiring provided between the first coil segment and the second coil segment and configured to connect the first coil segment and the second coil segment without disconnection and change directions of electric currents such that that the electric current flows through the first coil segment in the forward direction and the electric current flows through the second coil segment in a direction opposite to the forward direction.

FIG. 7 is a schematic diagram illustrating details of the winding frame 250 and the superconducting coil 200. In FIG. 7, the winding frame 250 and superconducting coil 200 are depicted separately to facilitate explanation.

As shown on the right side of FIG. 7, the first coil segment 210 is composed of a plurality of first sub-coil segments 211. These plurality of first sub-coil segments 211 are formed of one superconducting wire without using the superconducting joint. Note that the first coil segment 210 may be composed of only one first sub-coil segment 211, i.e., number of the first sub-coil segments 211 can be one.

Similarly, the second coil segment 220 is composed of a plurality of second sub-coil segments 221. These plurality of second sub-coil segments 221 are also formed of one superconducting wire without using the superconducting joint. Note that the second coil segment 220 may be composed of only one second sub-coil segment 221, i.e., number of the second sub-coil segments 221 can be one.

As shown on the left side of FIG. 7, on the winding frame 250, a guide structure 260 for defining (or accurately determining) the respective winding positions of the first sub-coil segments 211, the second sub-coil segments 221, and the intermediate wiring are formed.

The guide structure 260 includes, for example, steps 261 and a groove 262 as well as holes and rails as described below. The steps 261 and the groove 262 are formed by forming a plurality of steps on the outer periphery (or circumference) of the cylindrical member such that the winding frame has a plurality of different outer diameters along the direction of the central axis of the cylindrical member.

In order to obtain desired static magnetic field distribution, the radial position and/or the position in the central axis direction of each first sub-coil segment 211 and each second sub-coil segment 221 are determined by calculation in advance, for example. The guide structure 260 such as the steps 261 and the groove 262 may be determined based on the determined radial position and central axial position.

The winding frame 250 may include a fixing means, such as fixing brackets and a fixing band, for fixing each first sub-coil segment 211, each second sub-coil segment 221, and/or the intermediate wiring 230.

As described above, the superconducting magnet 10 of the embodiment is configured to avoid using any superconducting joint or to reduce the number the superconducting joint as much as possible. FIG. 8A schematically illustrates a configuration of a conventional superconducting magnet 600 and a superconducting joint SJ used therein, as a comparative example of the superconducting magnet 10 of the embodiment.

The conventional superconducting magnet 600 includes a plurality of separate superconducting coils that are connected together by the superconducting joint. For example, in the aspect shown in FIG. 8A, the conventional superconducting magnet 600 includes four superconducting coils 610, 620, 630, 640 that are separate from each other, wound by two winding frames 650 and 660, and are connected by using four superconducting joints (SJs).

By contrast, in the above-described superconducting magnet 10 of the embodiment shown in FIG. 8B, each of the first coil segment 210, the second coil segment 220, and the intermediate wiring 230 constituting the superconducting coil 200 is formed of a superconducting wire, which is one continuous wire, without using the superconducting joint. Moreover, only one superconducting joint is used to connect both ends of the superconducting coil 200.

In this manner, the superconducting magnet 10 of the embodiment is significantly reduced in number of the superconducting joint as compared with the conventional superconducting magnet 600. Consequently, the resistance value of the superconducting joint is also reduced, and thus, the duration time of the persistent current mode can be lengthened.

The second coil segment 220 may be configured such that the second coil segment 220 is wound close to (or adjacent to) the first coil segment 210, and part or all of the winding portion of the second coil segment 220 is substantially a non-inductive winding with respect to the first coil segment 210.

(Modifications of Superconducting Magnet)

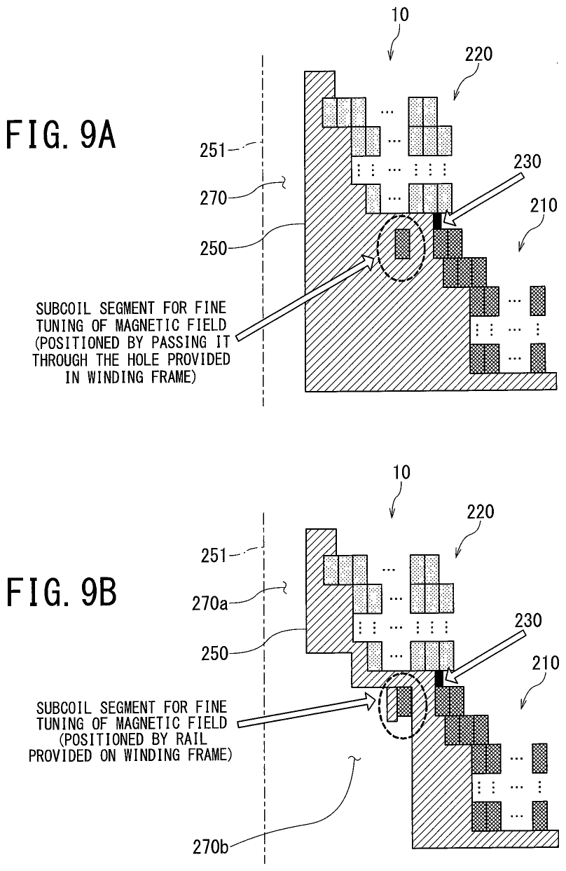

FIG. 9A is a schematic diagram illustrating a configuration of the superconducting magnet 10 according to the first modification of the embodiment. The configuration of the first modification includes a sub-coil segment for fine adjustment of the magnetic field. For positioning this sub-coil segment, a hole is formed in the winding frame 250 for passing the sub-coil segment.

FIG. 9B is a schematic diagram illustrating a configuration of the superconducting magnet 10 according to the second modification of the embodiment. In the second modification, in addition to the hollow region 270a, a hollow region 270b with different inner diameters corresponding to different outer diameters is also formed in the cylindrical member. Providing the hollow region 270b in the cylindrical member can reduce the weight of the superconducting magnet 10.

As shown in FIG. 9B, the sub-coil segment for fine adjustment of the magnetic field is positioned by a rail as the guide structure 260 of the winding frame 250.

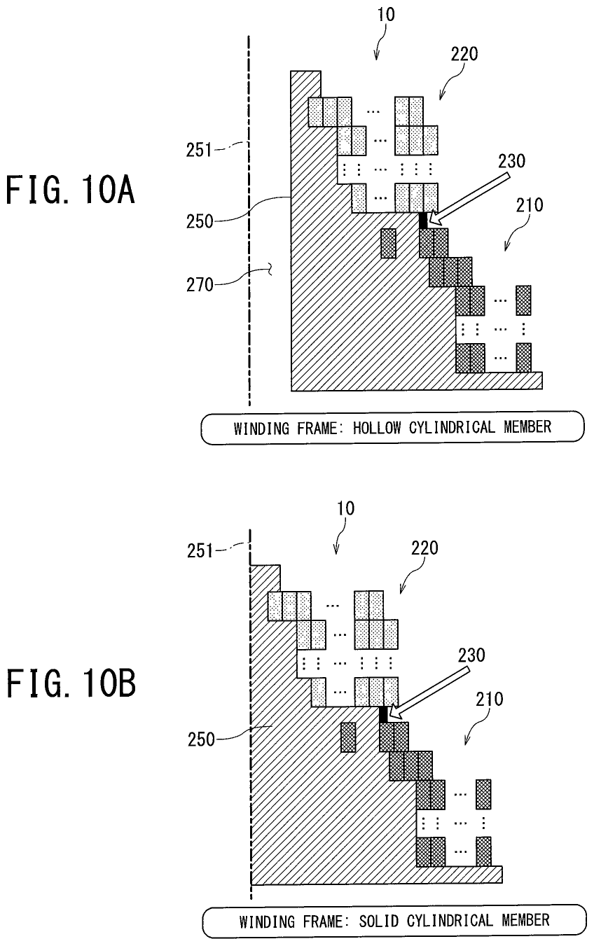

FIG. 10B is a schematic diagram illustrating a configuration of the superconducting magnet 10 according to the third modification of the embodiment. FIG. 10A is the same diagram as the first modification (FIG. 9A) for comparison with the third modifications.

In the third modification, the cylindrical member is formed to be solid with no hollow region 270 in the center of the cylinder, unlike the first embodiment and its first and second modifications. The third modification is a configuration peculiar to the flat-plate superconducting magnet 10. In the superconducting magnet 10 according to the third modification, the imaging space in which the object is placed during imaging is formed in the axial direction of the cylindrical member but outside the winding frame 250.

FIG. 11A is a schematic diagram illustrating a configuration of the superconducting magnet 10 according to the fourth modification of the embodiment, and FIG. 11B illustrates its equivalent circuit. The superconducting magnet 10 according to the fourth modification includes a third coil segment 240 and a persistent current switch 242 in addition to the first coil segment 210, the second coil segment 220, and the intermediate wiring 230. As shown in FIG. 11B, the persistent current switch 242 is provided between the third coil segment 240 and at least one of the first coil segment 210 and the second coil segment 220.

FIG. 11B also illustrate: a persistent magnet power supply 160; and a persistent current switch 150 for shifting the superconducting magnet 10 from the excitation mode to the persistent current mode, as external configurations of the superconducting magnet 10.

The third coil segment 240 is configured to generate a magnetic field that cancels all or part of the magnetic field generated by the first coil segment 210 and/or the second coil segment 220 when the persistent current switch 242 is turned on. The strength and distribution shape of the static magnetic field can be adjusted with higher flexibility by the third coil segment 240 and the persistent current switch 242.

Although two flat-plate superconducting magnets 10 facing each other have been described as the superconducting magnets 10 used in an open MRI apparatus so far, it can be provided with only one of the flat superconducting magnets 10. For example, in FIG. 3, only one superconducting magnet 10 below the top plate 51 may be provided.

According to the superconducting magnet of at least one embodiment described above, the static magnetic field distribution of the superconducting magnet can be formed with a higher degree of freedom, and the persistent current mode of the superconducting magnet can be continued for a longer time.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A superconducting magnet comprising:
at least one set of coil segment including
a first coil segment formed of a superconducting wire through which an electric current flows in a forward direction, and
a second coil segment formed of the superconducting wire through which an electric current flows in a direction opposite to the forward direction; and
at least one intermediate wiring provided between the first coil segment and the second coil segment and configured to
connect the first coil segment and the second coil segment without disconnection and
change directions of electric currents such that that the electric current flows through the first coil segment in the forward direction and the electric current flows through the second coil segment in a direction opposite to the forward direction.

2. The superconducting magnet according to claim 1, wherein the first coil segment, the second coil segment, and the intermediate wiring are formed of one continuous superconducting wire without using a superconducting joint, in which separate superconducting wires are connected by using a predetermined joint means.

3. The superconducting magnet according to claim 1, wherein:
the second coil segment is wound adjacent to the first coil segment; and
part or all of a winding portion of the second coil segment is substantially a non-inductive winding.

4. The superconducting magnet according to claim 1, wherein the intermediate wiring is configured such that a direction of the electric current flowing through the first coil segment is opposite to a direction of the electric current flowing through the second coil segment, and further configured to be non-inductively wound such that strength of a magnetic field generated by the intermediate wiring becomes substantially zero.

5. The superconducting magnet according to claim 2, further comprising a winding frame that winds around the superconducting wire,
wherein each of the first coil segment, the second coil segment, and the intermediate wiring is formed by winding the one superconducting wire at a different position on the winding frame.

6. The superconducting magnet according to claim 2, further comprising a winding frame that winds around the superconducting wire, wherein:
the first coil segment is composed of one or more first sub-coil segments that are formed of the one superconducting wire without using the superconducting joint;
the second coil segment is composed of one or more second sub-coil segments that are formed of the one superconducting wire without using the superconducting joint; and
a guide structure for defining respective winding positions of the one or more first sub-coil segments, the one or more second sub-coil segments, and the intermediate wiring is formed on the winding frame.

7. The superconducting magnet according to claim 6, wherein respective winding positions of the one or more first sub-coil segments and the one or more second sub-coil segments are determined based on predetermined static magnetic field distribution.

8. The superconducting magnet according to claim 6, wherein the guide structure includes at least one of a step, a groove, a hole, and a rail that are formed along a circumferential direction of the winding frame.

9. The superconducting magnet according to claim 6, wherein the winding frame includes a fixing means configured to fix at least one of the one or more first sub-coil segments, the one or more second sub-coil segments, and the intermediate wiring, which are all positioned by the guide structure.

10. The superconducting magnet according to claim 6, wherein:
the winding frame is configured by forming a plurality of steps on an outer periphery of a cylindrical member in such a manner that the winding frame has a plurality of different outer diameters along an axial direction of the cylindrical member; and
the cylindrical member is formed to have a hollow region corresponding to an imaging space in which an object is placed during imaging.

11. The superconducting magnet according to claim 10, wherein the hollow region of the cylindrical member is formed to have a plurality of different inner diameters corresponding to the plurality of different outer diameters.

12. The superconducting magnet according to claim 6, wherein:
the winding frame is configured by forming a plurality of steps on an outer periphery of a cylindrical member in such a manner that the winding frame has a plurality of different outer diameters along an axial direction of the cylindrical member;
the cylindrical member is formed to be solid; and
an imaging space in which an object is placed during imaging is a region in an axial direction of the cylindrical member but outside the winding frame.

13. The superconducting magnet according to claim 1, further comprising:
a third coil segment; and
a persistent current switch provided between the third coil segment and at least one of the first coil segment and the second coil segment,
wherein the third coil segment is configured to generate, when the persistent current switch is turned on, a magnetic field that cancels all or part of a magnetic field generated by the at least one of the first coil segment or the second coil segment.

14. An MRI apparatus comprising the superconducting magnet according to claim 1.
